(19) United States
(12) Patent Application Publication
(10) Pub. No.: US 2009/0009046 A1
(43) Pub. Date: Jan. 8, 2009

(54) Light emitting display and method of manufacturing the same

(76) Inventors: Min-ho OH, Suwon-si (KR); Yoon-hyeung Cho, Suwon-si (KR); Byoung-duk Lee, Suwon-si (KR); So-young Lee, Suwon-si (KR); Sun-young Lee, Suwon-si (KR); Won-jong Kim, Suwon-si (KR); Yong-tak Kim, Suwon-si (KR); Jin-baek Choi, Suwon-si (KR); Jong-hyuk Lee, Suwon-si (KR); Seung-han Lee, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 12/215,610

(22) Filed: Jun. 27, 2008

(30) Foreign Application Priority Data
Jun. 28, 2007 (KR) 10-2007-0064293

(51) Int. Cl. H01J 61/94; H01J 9/00

(52) U.S. Cl. 313/1; 445/23

(57) ABSTRACT

A light emitting display and a method of manufacturing the same, wherein the light emitting display includes a first substrate on which a plurality of light emitting devices is formed, a second substrate provided to face the first substrate, a dam member provided between the first substrate and the second substrate to surround the plurality of light emitting devices, an inorganic sealing material provided between the first substrate and the second substrate on an outer circumference of the dam member to attach the first substrate and the second substrate to each other, and a filling material provided on an internal side of the dam member to cover the plurality of light emitting devices. The inorganic sealing material effectively shields moisture or oxygen and/or increases the life of the light emitting display. The filling material fills the space between the substrates to improve mechanical reliability.

### CROSS-REFERENCE TO RELATED APPLICATION

This application claims priority to and the benefit of Korean Patent Application No. 10-2007-0064293, filed on Jun. 28, 2007, in the Korean Intellectual Property Office, the entire contents of which is incorporated herein by reference.

### BACKGROUND

1. Technical Field

This disclosure relates to a light emitting display and a method of manufacturing the same, and more particularly to, a light emitting display seal comprising an inorganic sealing material and a method of manufacturing the same.

2. Discussion of Related Art

Since a light emitting device such as an organic light emitting diode (OLED) includes organic materials vulnerable to moisture and/or oxygen, it is desirable to protect the OLED against moisture and/or oxygen.

Since a light emitting display using an OLED typically has a wide viewing angle, high contrast and response speed, and low power consumption, in spite of its vulnerability to moisture and/or oxygen, light emitting displays are widely used in personal portable apparatus, such as MP3 players, mobile telephones, and televisions (TV). The thicknesses of light emitting displays have been gradually reduced in accordance with the requests of users.

However, when the thickness of a substrate of a light emitting display is reduced to no more than about 0.3 mm in order to reduce the thickness thereof, it is difficult to maintain the mechanical integrity of the device under stresses such as falling and twisting. Loss of mechanical integrity can compromise the sealed state of the device, thereby reducing the life of the organic light emitting display.

### SUMMARY OF THE INVENTION

Accordingly, it is an object to provide a light emitting display capable of securing mechanical reliability and of increasing a life and a method of manufacturing the same.

It is another object to provide a light emitting display capable of securing mechanical reliability while using an inorganic sealing material that effectively prevents moisture or oxygen from penetrating and a method of manufacturing the same.

Some embodiments provide a light emitting display comprising an improved sealing system and a method of manufacturing the same, the light emitting display comprising a first substrate on which a plurality of light emitting devices is disposed; a second substrate facing the plurality of light emitting devices; an inorganic seal disposed between the first substrate and the second substrate, and around a circumference of the second substrate; a dam member disposed between the first substrate and the second substrate and inward of the inorganic seal; and a filling material disposed filling the space defined by the first substrate, the second substrate, and the dam member. Embodiments of the display exhibit one or more of improved resistance to moisture and/or oxygen infiltration, and improved mechanical reliability of the seal. Some embodiments also exhibit reduced Newton's ring.

In order to achieve the foregoing and/or other objects, according to one aspect, there is provided a light emitting display including a first substrate on which a plurality of light emitting devices is formed, a second substrate provided to face the first substrate, a dam member provided between the first substrate and the second substrate to surround the plurality of light emitting devices, an inorganic sealing material provided between the first substrate and the second substrate on an outer circumference of the dam member to attach the first substrate and the second substrate to each other, and a filling material provided on an internal side of the dam member to cover the plurality of light emitting devices.

According to another aspect, there is provided a method of manufacturing a light emitting display including providing a first substrate on which a plurality of light emitting devices is formed, providing a second substrate, forming an inorganic sealing material on an outer circumference of the second substrate, forming a dam member on the second substrate on an internal side of the inorganic sealing material to surround the plurality of light emitting devices, dropping a liquid filling material to an inside of the dam member, providing the first substrate and the second substrate to face each other, and attaching the inorganic sealing material to the first substrate and the second substrate to seal up the plurality of light emitting devices.

Some embodiments provide a light emitting display comprising: a first substrate comprising a plurality of light emitting devices disposed thereon; a second substrate facing the plurality of light emitting devices disposed on the first substrate; a dam member disposed between the first substrate and the second substrate, surrounding the plurality of light emitting devices; an inorganic sealing material securing the first substrate and the second substrate to each other, disposed between the first substrate and the second substrate and around an outer circumference of the dam member to attach the first substrate and the second substrate; and a filling material inward of the dam member and between the first substrate and the second substrate, covering the plurality of light emitting devices.

In some embodiments, the dam member comprises an inorganic material. In some embodiments, the inorganic material comprises frit. In some embodiments, a reflecting layer that reflects laser and/or infrared (IR) radiation is disposed on a surface of the dam member. In some embodiments, the reflecting layer comprises at least one of Au, Ag, Pt, and Al. In some embodiments, at least a portion of the dam member contacts the inorganic sealing material. In some embodiments, dam member does not contact the inorganic sealing material.

In some embodiments, the dam member comprises an organic material. In some embodiments, the organic material comprises at least one of epoxy, epoxy acrylate, urethane, urethane acrylate, urethane acrylic, allyl resin, silicone, bisphenol A type epoxy silicone, cycloaliphatic epoxy silicone resin, acrylic epoxy silicone resin, allyl ether silicone, allyl methacrylate silicone, phenyl silicone resin, aliphatic urethane acrylate, and rubber.

In some embodiments, the dam member and the inorganic sealing material are separated from each other by at least about 50 μm.

In some embodiments, the inorganic sealing material comprises frit. In some embodiments, the frit is meltable by laser and/or IR radiation. In some embodiments, the frit comprises a transition metal compound.

In some embodiments, the filling material fills at least some of a space between the plurality of light emitting devices and the second substrate inward of the dam member. In some embodiments, at least a portion of the filling material contacts the dam member. In some embodiments, at least a portion of the filling material contacts the second substrate. In some embodiments, the filling material comprises a solid material. In some embodiments, the filling material comprises a heat, electron beam, and/or UV radiation hardening material. In some embodiments, the filling material comprises at least one of epoxy, epoxy acrylate, urethane, urethane acrylate, urethane acrylic, allyl resin, silicone, bisphenol A type epoxy silicone, cycloaliphatic epoxy silicone resin, acrylic epoxy silicone resin, allyl ether silicone, allyl methacrylate silicone, phenyl silicone resin, aliphatic urethane acrylate, and rubber.

In some embodiments, the filling material comprises a liquid material. In some embodiments, the filling material comprises silicone and/or silicone oil. In some embodiments, the filling material comprises at least one of hexamethyldisiloxane, octamethyltrisiloxane, decamethyltetrasioxane, dodecamethylpentasiloxane, and polydimethylsiloxanes.

Some embodiments provide a method of manufacturing a light emitting display comprising: providing a first substrate comprising a plurality of light emitting devices are formed; providing a second substrate facing the plurality of light emitting devices disposed on the first substrate; disposing an inorganic sealing material on an outer circumference of the second substrate; disposing a dam member on the second substrate inward of the inorganic sealing material and surrounding the plurality of light emitting devices; disposing a liquid filling material inward of the dam member; and securing the inorganic sealing material to the first substrate and the second substrate, thereby sealing up the plurality of light emitting devices.

In some embodiments, disposing the inorganic sealing material comprises: applying frit paste; and drying and/or annealing the frit paste.

In some embodiments, disposing the dam member comprises: applying frit paste; and drying and/or annealing the frit paste, thereby hardening the frit paste. In some embodiments, at least a portion of the dam member contacts the inorganic sealing material. In some embodiments, disposing the dam member comprises: applying a liquid organic material, wherein the liquid organic material does not contact the inorganic sealing material; and hardening the liquid organic material.

In some embodiments, securing the inorganic sealing material to the first substrate and the second substrate to face each other is performed at a pressure lower than atmospheric pressure. In some embodiments, the pressure is from about 1 Pa to about 10,000 Pa.

Some embodiments further comprise compressing the first substrate and the second substrate, thereby filling with the liquid filling material spaces between the light emitting devices and the second substrate within the dam member. Some embodiments further comprise hardening the liquid filling material.

In some embodiments, securing the inorganic sealing material to the first substrate and the second substrate comprises melting the inorganic sealing material. In some embodiments, the inorganic sealing material is melted by laser and/or IR radiation.

### BRIEF DESCRIPTION OF THE DRAWINGS

These and/or other embodiments and features will become apparent and more readily appreciated from the following description of certain exemplary embodiments, taken in conjunction with the accompanying drawings of which:

FIG. 1 is a perspective view illustrating an embodiment of a light emitting display;

FIG. 2 is a cross-sectional view taken along section line I1-I2 of FIG. 1;

FIGS. 3A and 3B are plan views illustrating an embodiments of a method of manufacturing the light emitting display; and

FIGS. 4A to 4F are cross-sectional views illustrating the embodiment of the method of manufacturing the light emitting display.

### DETAILED DESCRIPTION OF EXEMPLARY EMBODIMENTS

Hereinafter, certain exemplary embodiments will be described with reference to the accompanying drawings. Here, when a first element is described as being coupled to a second element, the first element may be not only directly coupled to the second element but may also be indirectly coupled to the second element via one or more third elements. Further, elements that are not essential to a complete understanding are omitted for clarity. Also, like reference numerals refer to like elements throughout.

In order to increase the life of an organic light emitting display, some embodiments use an inorganic sealing material that effectively prevents moisture and/or oxygen from penetrating. However, when an inorganic sealing material is used, mechanical reliability deteriorates in some embodiments.

Therefore, some embodiments provide a light emitting display capable of increasing a life and of improving mechanical reliability using an inorganic sealing material that effectively prevents moisture and/or oxygen from penetrating and a method of manufacturing the same.

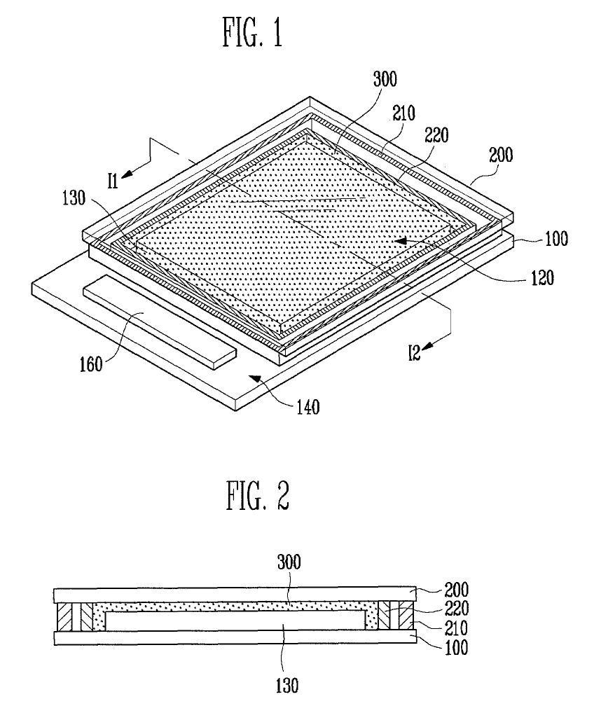

FIG. 1 is a perspective view illustrating an embodiment of a light emitting display. FIG. 2 is a cross-sectional view taken along section line I1-I2 of FIG. 1.

Referring to FIGS. 1 and 2, the light emitting display includes a substrate 100 on which a plurality of light emitting devices 130 is formed, a sealing substrate 200 facing the substrate 100, a dam member 220 provided between the substrate and the sealing substrate 200, which surrounds the plurality of light emitting devices 130, an inorganic sealing material 210 provided between the substrate 100 and the sealing substrate 200 outside the dam member 220, which couples the substrate 100 with the sealing substrate 200, an a filling material 300 provided inside the dam member 220 to cover the plurality of light emitting devices 130.

The substrate 100 is divided into a pixel region 120 and a non-pixel region 140 around the pixel region 120. The plurality of light emitting devices 130 is formed in the pixel region 120 and a driving circuit 160 for driving the plurality of light emitting devices 130 is formed in the non-pixel region 140. The light emitting devices 130 can be formed of organic light emitting diodes (OLED) that include anode electrodes, organic thin layers, and cathode electrodes.

The sealing substrate 200 is provided to overlap the pixel region 120 and a part of the non-pixel region 140. In the case of a front emission type of display, the sealing substrate 200 can be formed of a transparent material such as glass. In the case of a rear emission type, the sealing substrate can be formed of an opaque material.

The inorganic sealing material 210 can comprise frit, which is melted by laser or infrared red (IR) rays to the substrate 100 and the sealing substrate 200. The inorganic sealing material 210 is provided between the substrate 100 and the sealing substrate 200 surrounding the light emitting devices 130 so that moisture and/or oxygen penetration from the outside is prevented and/or reduced.

The dam member 220 prevents the flow of the filling material 300 so that the shape of the filling material 300 is maintained. The dam member 220 an inorganic material or an organic material. Also, the dam member 220 reduces or prevents heat from being transmitted to the light emitting devices 130 when the inorganic sealing material 210 is attached to the substrate 100 and the sealing substrate 200.

When the dam member 200 comprises an inorganic material or an organic material, frit can be used as the inorganic material. In this case, frit that transmits or reflects IR rays is used or a reflecting layer is formed on the surface of the dam member 220 using metal having a high reflectance in an IR region such as Au, Ag, Pt, and/or Al so that laser or IR radiation is reflected. In addition, epoxy, epoxy acrylate, urethane, urethane acrylate, urethane acrylic, allyl resin, silicone (such as bisphenol A type epoxy, cycloaliphatic epoxy resin, acrylic epoxy resin, allyl ether, allyl methacrylate, and phenyl silicone resin), aliphatic urethane acrylate, rubber, and combinations thereof can be used as the organic material.

The dam member 220 may contact the inorganic sealing material 210 or may be separated from the inorganic sealing material 210 by a predetermined distance. For example, the dam member 220 can contact the inorganic sealing material 210 when the dam member 220 comprises inorganic material, and can be separated from the inorganic sealing material 210 by about 50 μm when the dam member 220 comprises organic material.

When the dam member 220 comprising an organic material contacts the inorganic sealing material 210, in some embodiments, the dam member 220 is thermally decomposed when the inorganic sealing material 210 is attached to the substrate 100 and the sealing substrate 200, thereby generating out gas.

The filling material 300 is provided on the internal side of the region defined by the dam member 220 to cover the light emitting devices 130. In the illustrated embodiment, the filling material 300 is provided between the light emitting devices 130 and the sealing substrate 200 to contact the dam member 220 and the sealing substrate 200. The filling material 300 can comprise a colorless solid or liquid material having a transmittance of no less than about 95% within a thickness of about 30 μm.

For example, the solid material can comprise at least one of epoxy, epoxy acrylate, urethane, urethane acrylate, urethane acrylic, allyl resin, silicone (such as bisphenol A type epoxy, cycloaliphatic epoxy resin, acrylic epoxy resin, allyl ether, allyl methacrylate, and phenyl silicone resin), aliphatic urethane acrylate, and rubber. After a liquid material is filled therein, it may be hardened by heat, electron beam, or UV radiation. In some embodiments, the liquid material is molded into a film which is attached to the solid material.

In addition, a liquid material can be silicone or silicone oil that exhibits no change in phase and a volume change ratio within 5% at temperatures ranging from about −40° C. to about 100° C., for example, comprising at least one material selected from the group consisting of hexamethyldisiloxane, octamethyltrisiloxane, decamethyltetrasioxane, dodecamethylpentasiloxane, polydimethylsiloxane, etc.

A method of manufacturing a light emitting display will now be described in detail.

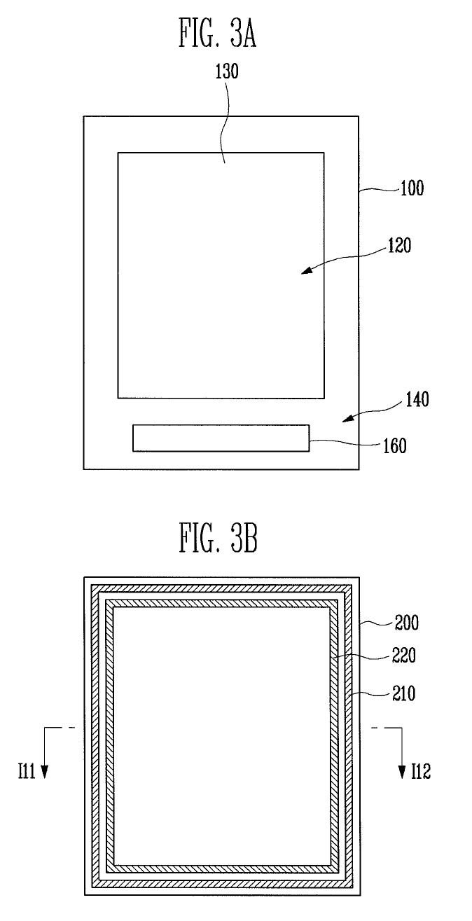

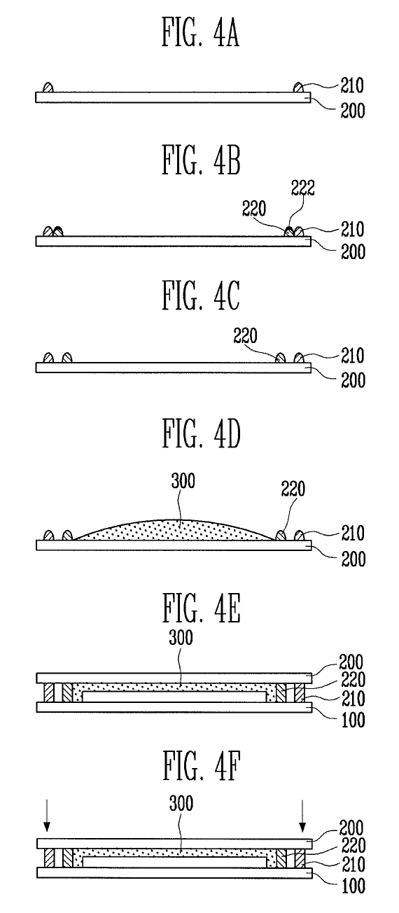

FIGS. 3A and 3B are plan views illustrating an embodiment of a method of manufacturing the light emitting display. FIGS. 4A to 4F are cross-sectional views illustrating the embodiment of the method of manufacturing the light emitting display. FIGS. 4A to 4D are cross-sectional views taken along section line I11-I12 of FIG. 3B.

Referring to FIG. 3A, first, the substrate 100 on which the plurality of light emitting devices 130 is formed is provided. The substrate is divided into the pixel region 120 and the non-pixel region 140 around the pixel region 120. The plurality of light emitting devices 130 can be formed in the pixel region 120 of the substrate and the driving circuit 160 for driving the light emitting devices 130 can be formed in the non-pixel region 140.

The light emitting devices 130 comprise the OLED including the anode electrodes, the organic thin layers, and the cathode electrodes. The light emitting devices 130 can further include thin film transistors (TFT) for controlling the operation of the OLEDs and capacitors for maintaining signals. Processes of manufacturing the OLED are illustrated in the Korean Patent Publication Nos. 2002-0047889 (published on Jun. 22, 2002) and 2003-0092873 (published Dec. 6, 2003), the entire disclosures of which are incorporated by reference.

Referring to FIGS. 3B and 4A, the sealing substrate 200 for sealing the light emitting devices 130 of the pixel region 120 is provided. The sealing substrate 200 can overlap the pixel region 120 and a part of the non-pixel region 140. A transparent substrate such as glass having the front emission structure or an opaque substrate having the rear emission type can be used as the sealing substrate 200.

An inorganic sealing material 210 is disposed on the outer circumference of the sealing substrate 200. The inorganic sealing material 210 can comprise frit using dispensers and/or using a screen printing method. Frit commonly means the powder-type raw material of glass. However, as used herein, frit refers to a paste comprising a laser or IR ray absorbing material, an organic binder, and a filler for reducing a thermal expansion coefficient, to a main material such as SiO₂. After a drying or annealing process, the organic binder and moisture are removed from the paste frit so that the paste frit is hardened. Laser or IR ray absorbing material can include a transition metal compound, for example, a vanadium compound.

After the inorganic sealing material 210 is disposed on the internal side of the sealing substrate 200, a washing process can be performed.

Referring to FIGS. 3B, 4B, and 4C, the dam member 220 is disposed on the sealing substrate 200 on the inward or internal side of the inorganic sealing material 210, thereby surrounding the pixel region 120. The dam member 220 can comprise an inorganic material and/or an organic material, and is applied by any suitable method, for example using dispensers or by screen printing. At this time, the amount of the inorganic material and/or organic material is determined in consideration of the distance from the light emitting devices 130 on the outermost circumference of the pixel region to the inorganic sealing material 210 and the height of the dam member 220. The height of the dam member 220 can be determined by the height of the inorganic sealing material 210 so that the height of the inorganic sealing material 210 is about equal to or less than the height of the dam member 220.

Frit can be used as the inorganic material. In this case, the dam member 220 can be formed in a process of forming the inorganic sealing material 210. Frit that transmits or reflects laser or IR rays is used or a reflecting layer 222 is disposed on the surface of the dam member 220 in order to reflect laser or UV rays as illustrated in FIG. 4B. For example, after applying the paste frit, the paste frit is dried or annealed, and hardened to form the dam member 220. Then, the metal such as Au, Ag, Pt, and/or Al having a high reflectance in the UV ray region is applied onto the surface of the dam member 220 to form the reflecting layer 222. In addition, the organic material can be at least one of epoxy, epoxy acrylate, urethane, urethane acrylate, urethane acrylic, allyl resin, silicone (such as bisphenol A type epoxy, cycloaliphatic epoxy resin, acrylic epoxy resin, allyl ether, allyl methacrylate, and phenyl silicone resin), aliphatic urethane acrylate, and rubber.

The dam member 220 can contact the inorganic sealing material 210 as illustrated in FIG. 4B or can be separated from the inorganic sealing material 210 by a predetermined distance as illustrated in FIG. 4C. For example, when the dam member 220 is comprises an inorganic material, the dam member 220 can contact the inorganic sealing material 210. In this case, the area of the non-pixel region can be reduced. In addition, when the dam member comprises an organic material, the dam member 220 is separated from the inorganic sealing material 210 by no less than about 50 μm. Since the organic material typically has viscosity of not more than about 1,000,000 cps to be easily applied, the dam member 220 can be easily collapsed by stress such as a difference in pressure. Therefore, the dam member 220 can be hardened by heat, electron beam, or UV radiation in accordance with the kind of the organic material so that the dam member 220 is not damaged by the stress in a process of attaching the substrate 100 to the sealing substrate 200.

In another embodiment, in a process of forming the inorganic sealing material 210 or the dam member 220, a dummy sealing material (not shown) can be formed of epoxy and frit on the outermost circumference of the sealing substrate 200. The dummy sealing material is formed on the outside of the sealing material 210 to collectively seal up the space between the substrate 100 and the sealing substrate 200. In the case of a mother substrate on which a plurality of light emitting displays is simultaneously manufactured, the dummy sealing material is disposed on the outermost circumference thereof.

Referring to FIG. 4D, the filling material 300 is disposed on the sealing substrate 200 on the inward or internal side of the region defined by the dam member 220. The filling material 300 can comprise a colorless solid or liquid material having a thickness of less than about 30 μm and a transmittance of not less than about 95%. For example, the solid material can be selected from epoxy, epoxy acrylate, urethane, urethane acrylate, urethane acrylic, allyl resin, silicone (such as bisphenol A type epoxy, cycloaliphatic epoxy resin, acrylic epoxy resin, allyl ether, allyl methacrylate, and phenyl silicone resin), aliphatic urethane acrylate, rubber, and combinations thereof. The liquid material can be a silicone or silicone oil that exhibits no change in phase and a volume change ratio within about 5% in the temperature range of from about −40° C. to about 100° C. such as hexamethyldisiloxane, octamethyltrisiloxane, decamethyltetrasioxane, dodecamethylpentasiloxane, polydimethylsiloxane, or etc. After the sealing substrate 200 is filled with the filling material 300, the filling material 300 is cured and hardened by heat, electron beam, and/or UV radiation.

For example, the proper amount of liquid filling material 300 can applied to the sealing substrate 200 on the internal side of the dam member 220 using a one drop filling (ODF) device. In this case, the proper amount of filling material 300 in proportion to the volume of the internal space can be easily controlled.

Referring to FIG. 4E, the substrate 100 is disposed facing the sealing substrate 200. For example, after the substrate 100 is mounted on an upper chuck of an attaching device and the sealing substrate 200 is mounted on a lower chuck of the attaching device, the substrate 100 and the sealing substrate 200 are attached to each other. As the substrate 100 and the sealing substrate 200 are attached to each other, the light emitting devices 130 are covered with the filling material 300 and the flow of the filling material 300 is prevented by the dam member 220 so that the shape is maintained. At this time, the substrate 100 and the sealing substrate 200 are attached to each other under a pressure lower than atmospheric pressure, for example, from about 1 Pa to about 100,000 Pa so that bubbles and/or voids are not formed between the substrate 100 and the sealing substrate 200. In addition, the substrate 100 and the sealing substrate 200 are pressed together so that the space between the light emitting devices 130 and the sealing substrate 200 is completely filled with the filling material 300. The filling material 300 can be hardened by heat, electron beam, or UV radiation after the substrate 100 and the sealing substrate 200 are attached to each other.

Referring to FIG. 4F, laser and/or IR radiation are projected onto the inorganic sealing material 210 after the substrate 100 and the sealing substrate 200 are attached to each other. As the laser or IR rays are absorbed to generate heat, the inorganic sealing material 210 is attached to the substrate 100 and the sealing substrate 200 by melting, so that the light emitting devices 130 are sealed. Such a sealing process is performed after the dummy sealing material is hardened so that the space between the substrate 100 and the sealing substrate 200 is maintained.

When laser or IR radiation are projected onto the inorganic sealing material 210, a mask or a protecting film (not shown) is used so that laser or IR radiation are projected onto only a desired region. When the dam member 220 comprises an inorganic material that transmits or reflects laser or IR radiation, or the reflecting layer 222 is disposed on the surface of the dam member 220, the mask or the protecting film is disposed only in the pixel region 120 so that laser or IR radiation are not projected thereon. When the dam member 220 comprises an organic material, the mask or the protecting film is disposed in the pixel region 120 and the non-pixel region 140 where the dam member 220 is formed so that laser or IR rays does not projected thereon.

In some embodiments lacking a dam member 220, since the heat generated in irradiating with laser or IR radiation is easily transmitted to the filling material 300, the temperature can instantaneously rise, thereby melting the filling material 300. However, the transmission of heat is effectively reduced or prevented by the dam member 220, thereby thermally protecting the filling material 300.

According to the above embodiment, the inorganic sealing material 210 seals only the pixel region 120. In other embodiments, the inorganic sealing material 210 can also seal the driving circuit 160. In addition, according to the above embodiment, the inorganic sealing material 210 and the dam member 220 are integrated with each other on the sealing substrate 200. In other embodiments, the inorganic sealing material and the dam member can be integrated with each other on the substrate 100 to have a double or multiple structure. For example, in order to improve sealing effect, the inorganic sealing material 210 can comprise a double or multiple structure, and/or the dam member 220 comprise a double or multiple structure in order to improve heat shielding effect.

In addition, according to the above embodiment, the filling material 300 is filled before attaching the substrate 100 and the sealing substrate 200 to each other. However, the filling material 300 can be filled after the substrate 100 and the sealing substrate 200 are attached to each other in accordance with the material.

As an another embodiment, the curing of the filling material 300 dropped on the internal side of the dam member 220 is initiated by heat, electron beam, and/or UV before attaching the substrate 100 and the sealing substrate 200 to each other, and is completely cured and hardened after attaching the substrate 100 and the sealing substrate 200 to each other.

As described above, an inorganic sealing material that effectively shields moisture and/or oxygen seals the light emitting devices so that the life of the light emitting display is increased, and the space between the substrates is filled with the filling material so that mechanical reliability is improved.

In typical light emitting displays, since the space between the substrate and the sealing substrate is empty, the substrate can move, thereby generating Newton's ring and/or increasing the shock sensitivity of the light emitting display. On the other hand, according to some embodiments of the light emitting display, the space between the substrate and the sealing substrate is filled with a filling material with a similar refractivity to the refractivity of the glass substrate, thereby reducing or preventing Newton's ring. Therefore, visibility is improved and a voltage tolerance characteristic between the substrates is improved so that the seal is not as easily damaged by shock.

Although exemplary embodiments have been shown and described, those skilled in the art will appreciate that changes might be made in these embodiments without departing from the principles and spirit thereof, the scope of which is defined in the claims and their equivalents.

What is claimed is:

1. A light emitting display comprising:
a first substrate comprising a plurality of light emitting devices disposed thereon;
a second substrate facing the plurality of light emitting devices disposed on the first substrate;
a dam member disposed between the first substrate and the second substrate, surrounding the plurality of light emitting devices;
an inorganic sealing material securing the first substrate and the second substrate to each other, disposed between the first substrate and the second substrate and around an outer circumference of the dam member to attach the first substrate and the second substrate; and
a filling material inward of the dam member and between the first substrate and the second substrate, covering the plurality of light emitting devices.

2. The light emitting display as claimed in claim 1, wherein the dam member comprises an inorganic material.

3. The light emitting display as claimed in claim 2, wherein the inorganic material comprises frit.

4. The light emitting display as claimed in claim 2, wherein a reflecting layer that reflects laser and/or infrared (IR) radiation is disposed on a surface of the dam member.

5. The light emitting display as claimed in claim 4, wherein the reflecting layer comprises at least one of Au, Ag, Pt, and Al.

6. The light emitting display as claimed in claim 2, wherein at least a portion of the dam member contacts the inorganic sealing material.

7. The light emitting display as claimed in claim 1, wherein the dam member comprises an organic material.

8. The light emitting display as claimed in claim 7, wherein the organic material comprises at least one of epoxy, epoxy acrylate, urethane, urethane acrylate, urethane acrylic, allyl resin, silicone, bisphenol A type epoxy silicone, cycloaliphatic epoxy silicone resin, acrylic epoxy silicone resin, allyl ether silicone, allyl methacrylate silicone, phenyl silicone resin, aliphatic urethane acrylate, and rubber.

9. The light emitting display as claimed in claim 7, wherein the dam member does not contact the inorganic sealing material.

10. The light emitting display as claimed in claim 9, wherein the dam member and the inorganic sealing material are separated from each other by at least about 50 μm.

11. The light emitting display as claimed in claim 1, wherein the inorganic sealing material comprises frit.

12. The light emitting display as claimed in claim 11, wherein the frit is meltable by laser and/or IR radiation.

13. The light emitting display as claimed in claim 12, wherein the frit comprises a transition metal compound.

14. The light emitting display as claimed in claim 1, wherein the filling material fills at least some of a space between the plurality of light emitting devices and the second substrate inward of the dam member.

15. The light emitting display as claimed in claim 14, wherein at least a portion of the filling material contacts the dam member.

16. The light emitting display as claimed in claim 14, wherein at least a portion of the filling material contacts the second substrate.

17. The light emitting display as claimed in claim 1, wherein the filling material comprises a solid material.

18. The light emitting display as claimed in claim 17, wherein the filling material comprises a heat, electron beam, and/or UV radiation hardening material.

19. The light emitting display as claimed in claim 18, wherein the filling material comprises at least one of epoxy, epoxy acrylate, urethane, urethane acrylate, urethane acrylic, allyl resin, silicone, bisphenol A type epoxy silicone, cycloaliphatic epoxy silicone resin, acrylic epoxy silicone resin, allyl ether silicone, allyl methacrylate silicone, phenyl silicone resin, aliphatic urethane acrylate, and rubber.

20. The light emitting display as claimed in claim 1, wherein the filling material comprises a liquid material.

21. The light emitting display as claimed in claim 20, wherein the filling material comprises silicone and/or silicone oil.

22. The light emitting display as claimed in claim 20, wherein the filling material comprises at least one of hexamethyldisiloxane, octamethyltrisiloxane, decamethyltetrasioxane, dodecamethylpentasiloxane, and polydimethylsiloxanes.

23. A method of manufacturing a light emitting display comprising:
providing a first substrate comprising a plurality of light emitting devices are formed;
providing a second substrate facing the plurality of light emitting devices disposed on the first substrate;
disposing an inorganic sealing material on an outer circumference of the second substrate;
disposing a dam member on the second substrate inward of the inorganic sealing material and surrounding the plurality of light emitting devices;
disposing a liquid filling material inward of the dam member; and
securing the inorganic sealing material to the first substrate and the second substrate, thereby sealing up the plurality of light emitting devices.

24. The method as claimed in claim 23, wherein disposing the inorganic sealing material comprises:
applying frit paste; and
drying and/or annealing the frit paste.

25. The method as claimed in claim 23, wherein disposing the dam member comprises:
applying frit paste; and
drying and/or annealing the frit paste, thereby hardening the frit paste.

26. The method as claimed in claim 25, wherein at least a portion of the dam member contacts the inorganic sealing material.

27. The method as claimed in claim 23, wherein disposing the dam member comprises:
applying a liquid organic material, wherein the liquid organic material does not contact the inorganic sealing material; and
hardening the liquid organic material.

28. The method as claimed in claim 23, wherein securing the inorganic sealing material to the first substrate and the second substrate to face each other is performed at a pressure lower than atmospheric pressure.

29. The method as claimed in claim 28, wherein the pressure is from about 1 Pa to about 10,000 Pa.

30. The method as claimed in claim 23, further comprising compressing the first substrate and the second substrate, thereby filling with the liquid filling material spaces between the light emitting devices and the second substrate within the dam member.

31. The method as claimed in claim 23, further comprising hardening the liquid filling material.

32. The method as claimed in claim 23, wherein securing the inorganic sealing material to the first substrate and the second substrate comprises melting the inorganic sealing material.

33. The method as claimed in claim 32, wherein the inorganic sealing material is melted by laser and/or IR radiation.
